(19) United States
(12) Patent Application Publication
(10) Pub. No.: US 2019/0244946 A1
(43) Pub. Date: Aug. 8, 2019

(54) SEMICONDUCTOR PACKAGE HAVING A TSV STRUCTURE

(71) Applicant: SAMSUNG ELECTRONICS CO., LTD., SUWON-SI (KR)

(72) Inventor: YONG HOON KIM, SUWON-SI (KR)

(21) Appl. No.: 16/242,434

(22) Filed: Jan. 8, 2019

(30) Foreign Application Priority Data
Feb. 5, 2018 (KR) 10-2018-0013809

(51) Int. Cl. H01L 25/18; H01L 23/538; H01L 23/552; H01L 23/31; H01L 23/00; H01L 23/528

(52) U.S. Cl. CPC H01L 25/18; H01L 23/5384; H01L 23/5286; H01L 23/3128; H01L 24/17; H01L 23/552

(57) ABSTRACT

A semiconductor package includes a substrate. A vertically stacked chip structure including two semiconductor chips is mounted on the substrate. A third semiconductor chip is mounted on the substrate and is spaced apart horizontally from the vertically stacked chip structure. A package molding material is disposed on the substrate and covers sidewalls of the vertically stacked chip structure and covers sidewalls of the third semiconductor chip. An electromagnetic shielding layer extends along sidewalls of the package molding material and along an upper surface of the package molding material. The first semiconductor chip is disposed between the second semiconductor chip and the substrate. The first semiconductor chip is connected to a first grounding through via and a first signal/power through via. The second semiconductor chip is connected to a second grounding through via. The electromagnetic shielding layer is connected to the second grounding through via.

This application claims priority from Korean Patent Application No. 10-2018-0013809 filed on Feb. 5, 2018 in the Korean Intellectual Property Office, the disclosure of which is herein incorporated by reference in its entirety.

### TECHNICAL FIELD

The present disclosure relates to a semiconductor package, and more particularly, to a semiconductor package including a through via (TSV) structure.

### DISCUSSION OF THE RELATED ART

Semiconductor packages are casings that contain one or more semiconductor integrated circuits. Semiconductor packages are responsible for protecting the integrated circuit from impact and corrosion, providing electrical contacts for the integrated circuit, and for dissipating heat created by the integrated circuit. Modern semiconductor packages are being developed to encase smaller integrated circuits while dissipating more heat therefrom.

### SUMMARY

A semiconductor package includes a substrate having a first surface and a second surface opposite to the first surface. A vertically stacked chip structure is mounted on the first surface of the substrate. The stacked chip structure includes a first semiconductor chip and a second semiconductor chip disposed on the first semiconductor chip. A third semiconductor chip is mounted on the first surface of the substrate and is spaced apart horizontally from the stacked chip structure. A package molding material is disposed on the first surface of the substrate and covers sidewalls of the stacked chip structure and covers sidewalls of the third semiconductor chip. An electromagnetic shielding layer extends along sidewalls of the package molding material and along an upper surface of the package molding material. The first semiconductor chip is disposed between the second semiconductor chip and the substrate. The first semiconductor chip is connected to a first grounding through via and a first signal/power through via. The second semiconductor chip is connected to a second grounding through via. The electromagnetic shielding layer is connected to the second grounding through via.

A semiconductor package includes a substrate having a first surface and a second surface opposite to the first surface. A first semiconductor chip is mounted on the first surface of the substrate and connected to a plurality of first through vias. A second semiconductor chip is mounted on the second surface of the substrate and is spaced apart horizontally from the first semiconductor chip. A package molding material is disposed on the first surface of the substrate and covers sidewalls of the first semiconductor chip and covers sidewalls of the second semiconductor chip. An electromagnetic shielding layer extends along sidewalk of the package molding material and an upper surface of the package molding material and is connected to some of the plurality of first through vias.

A semiconductor package includes a substrate having a first surface and a second surface opposite to the first surface. A vertically stacked chip structure is mounted on the first surface of the substrate. The vertically stacked chip structure includes a first semiconductor chip and a second semiconductor chip disposed on the first semiconductor chip. A third semiconductor chip is mounted on the first surface of the substrate and is spaced apart horizontally from the vertically stacked chip structure. A package molding material is disposed on the first surface of the substrate and covers sidewalk of the vertically stacked chip structure and covers sidewalls of the third semiconductor chip. An electromagnetic shielding layer extends along sidewalk and an upper surface of the package molding material. The second semiconductor chip is disposed at a top of the vertically stacked chip structure. The first semiconductor chip is disposed between the second semiconductor chip and the substrate. The first semiconductor chip is connected to a plurality of first through vias. The second semiconductor chip is connected to a plurality of second through vias. A number of second through vias of the plurality of second through vias is different from a number of first through vias of the plurality of first though vias. The electromagnetic shielding layer is connected to the second through vias.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a schematic diagram illustrating a semiconductor package according to exemplary embodiments of the present disclosure;

FIG. 2 is a schematic diagram illustrating a semiconductor package according to exemplary embodiments of the present disclosure;

FIG. 3 is a schematic diagram illustrating a semiconductor package according to exemplary embodiments of the present disclosure;

FIG. 4 is a schematic diagram illustrating a semiconductor package according to exemplary embodiments of the present disclosure;

FIG. 5 is a schematic diagram illustrating a semiconductor package according to exemplary embodiments of the present disclosure;

FIG. 6 is a schematic diagram illustrating a semiconductor package according to exemplary embodiments of the present disclosure;

FIG. 7 is a schematic diagram illustrating a semiconductor package according to exemplary embodiments of the present disclosure;

FIG. 8 is a schematic diagram illustrating a semiconductor package according to exemplary embodiments of the present disclosure;

FIG. 9 is a schematic diagram illustrating a semiconductor package according to exemplary embodiments of the present disclosure;

FIG. 10 is a schematic diagram illustrating a semiconductor package according to exemplary embodiments of the present disclosure; and

FIG. 11 is a schematic diagram illustrating a semiconductor package according to exemplary embodiments of the present disclosure.

### DETAILED DESCRIPTION OF THE EMBODIMENTS

Hereinafter, exemplary embodiments of the present disclosure will be described in detail with reference to the accompanying drawings. In the description, specific terminology is employed for sake of clarity. However, the present disclosure is not intended to be limited to the specific terminology so selected, and it is to be understood that each specific element includes all technical equivalents which operate in a similar manner.

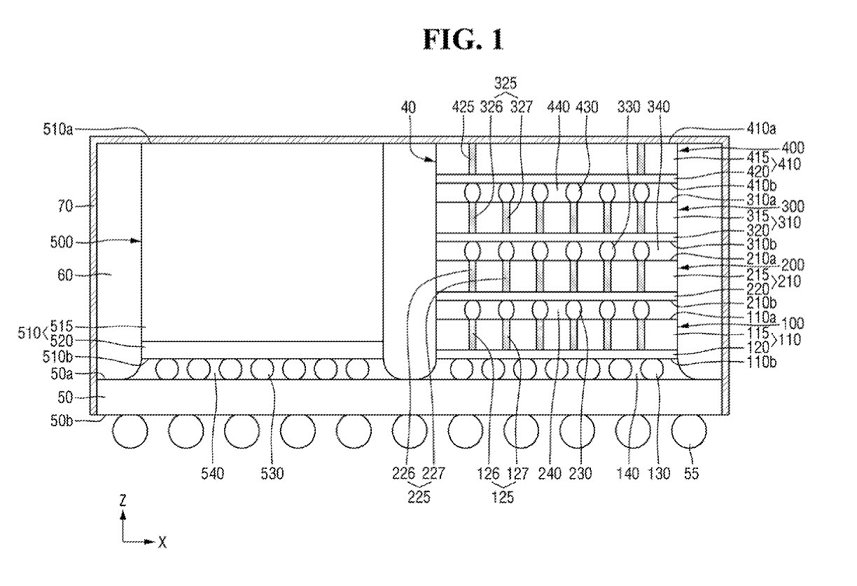

FIG. 1 is a schematic diagram illustrating a semiconductor package according to exemplary embodiments of the present disclosure.

Referring to FIG. 1, a semiconductor package, according to exemplary embodiments of the present disclosure, may include a mounting substrate 50, a stacked chip structure 40, a fifth semiconductor chip 500, a package molding material 60, and a shielding layer 70 for shielding electromagnetic waves.

The mounting substrate 50 may be a packaging substrate. For example, the mounting substrate 50 may be a printed circuit board (PCB) or a redistributed layer (RDL) substrate. The redistribution layer (RDL) substrate may be formed by forming a redistribution wiring layer and external terminals 55 in the stacked chip structure 40 and the fifth semiconductor chip 500 at a wafer level, without a printed circuit board.

The mounting substrate 50 includes a first surface 50a and a second surface 50b that is opposite to the first surface 50a.

The external terminals 55 may be disposed on the second surface 50b of the mounting substrate 50. The external terminals 55 may electrically connect the semiconductor package to an external device. The external terminals 55 may provide an electrical signal to the stacked chip stricture 40 and/or the fifth semiconductor chip 500 or may provide an electrical signal from the stacked chip structure 40 and/or the fifth semiconductor chip to an external device.

The stacked chip structure 40 is formed by sequentially stacking a first semiconductor chip 100, a second semiconductor chip 200, a third semiconductor chip 300, and a fourth semiconductor chip 400 in the vertical direction (z-direction).

For example, the first semiconductor chip 100 may be disposed at the bottom of the stacked chip structure 40 and therefore the first semiconductor chip 100 may be the chip of the stacked chip structure 40 closest to the mounting substrate 50. The fourth semiconductor chip 400 may be disposed at the top of the stacked chip structure 40 and therefore the fourth semiconductor chip 400 may be the chip of the stacked chip structure 40 farthest from the mounting substrate 50.

The stacked chip structure 40 may be mounted on the first surface 50a of the mounting substrate 50. The stacked chip structure 40 may be electrically connected to the mounting substrate 50.

For example, the first to fourth semiconductor chips 100, 200, 300 and 400 may each be semiconductor memory chips. The semiconductor memory chips may be volatile semiconductor memory chips such as a dynamic random access memory (DRAM) or a static random access memory (SRAM), or may be non-volatile semiconductor memory chips such as a phase-change random access memory (PRAM), a magnetoresistive random access memory (MRAM), FeRAM (Ferroelectric Random Access Memory) or RRAM (Resistive Random Access Memory). The fifth semiconductor chip 500 may be an application processor (AP) or a central processing unit (CPU) having one or more cores.

For example, the first semiconductor chip 100 may be a logic chip, and the second to fourth semiconductor chips 200, 300 and 400 may be semiconductor memory chips. The first semiconductor chip 100 may be a controller chip for controlling the operation of the second to fourth semiconductor chips 200, 300 and 400 electrically connected thereto.

Although the semiconductor package shown in FIG. 1 is illustrated as consisting of the four semiconductor chips stacked on one another, other numbers of chips may be included within the stacked chip structure 40.

The first semiconductor chip 100 may include a first chip substrate 110 and a first plurality of through vias 125.

The first chip substrate 110 may include a first surface 110a and a second surface 110b that is opposite to the first surface. The first chip substrate 110 may include a first semiconductor substrate 115 and a first semiconductor element layer 120. The first surface 110a of the first chip substrate 110 may be adjacent to the first semiconductor substrate 115, and the second surface 110b of the first chip substrate 110 may be adjacent to the first semiconductor element layer 120.

The first semiconductor substrate 115 may be a bulk silicon substrate or an SOI (silicon-on-insulator) substrate. Alternatively, the first semiconductor substrate 115 may be a silicon substrate or may be a substrate made of other materials including, but not limited to, silicon germanium, silicon germanium on insulator (SGOI), indium antimonide (InSb), lead-telluride (PbTe) compound, indium arsenide (InAs), indium phosphide (InP), gallium arsenide (GaAs), and gallium antimonide (GaSb).

The first semiconductor element layer 120 may include various kinds of individual devices and an interlayer dielectric layer. The plurality of individual devices may include a variety of microelectronic devices, for example, a metal-oxide-semiconductor field effect transistor (MOSFET) such as complementary metal-insulator-semiconductor transistors, a system LSI (large scale integration), a flash memory, a DRAM, an SRAM, an EEPROM, a PRAM, an MRAM or an RRAM, an image sensor such as a CIS (CMOS imaging sensor), a micro-electro-mechanical system (MEMS), an active element, a passive element, etc. The plurality of individual devices may be electrically connected to a conductive region formed in the first semiconductor substrate 115. The first semiconductor element layer 120 may include a conductive wiring or a conductive plug that electrically connects at least two of the plurality of individual elements to one another, or electrically connects the plurality of discrete elements to the conductive region of the first semiconductor substrate 115. In addition, the plurality of individual devices can be electrically disconnected from one another by the respective insulating layers.

The first chip substrate 110 may include a passivation layer including an insulating material on the first surface 110a and/or the second surface 110b of the first chip substrate 110.

The first semiconductor chip 100 includes a plurality of first through vias 125. The plurality of first through vias 125 may be formed in the first chip substrate 110. The plurality of first through vias 125 may penetrate the first semiconductor substrate 115.

The plurality of first through vias 125 may include first grounding through vias 126 and first signal/power through vias 127. The first signal/power through vias 127 may supply power or operation signals, etc. to the semiconductor element layers 120, 220, 320, and 420 included in the stacked chip structure 40. The first grounding through vias 126 are, for example, connected to the ground region.

Although the first through vias 125 are shown in FIG. 1 as not penetrating through the first chip substrate 110, one or more of the first through vias 125 may penetrate through the first chip substrate 110.

The shape of the first through vias 125 and their extension may vary depending on whether the first through vias 125 are formed before a front end of line (FEOL) process, between the front end of line (FEOL) process and a back end of line (BEOL) process, or during the BEOL process or after the BEOL process.

Connection pads connected to the first semiconductor element layer 120 and/or the first through vias 125 may be formed on the first surface 110a and the second surface 110b of the first chip substrate 110.

First connection terminals 130 may be formed on the second surface 110b of the first chip substrate 110. The first connection terminals 130 may be disposed between the first semiconductor chip 100 and the mounting substrate 50. The first connection terminals 130 may be disposed between the stacked chip structure 40 and the mounting substrate 50.

Although the first connection terminals 130 shown in FIG. 1 to have a ball shape, the present disclosure is not limited thereto. It is to be understood that the first connection terminals 130 may be of a solder bump type, each of which consisting of a pillar and a solder ball coupled with the pillar.

The second semiconductor chip 200 may be disposed on top of the first semiconductor chip 100. The first semiconductor chip 100 may be disposed between the second semiconductor chip 200 and the mounting substrate 50. The second semiconductor chip 200 may be disposed on the first surface 110a of the first chip substrate 110. The second semiconductor chip 200 may include a second chip substrate 210 and a plurality of second through vias 225.

The second chip substrate 210 may include a first surface 210a and a second surface 210b opposite to the first surface. The second chip substrate 210 may include a second semiconductor substrate 215 and a second semiconductor element layer 220. The first surface 210a of the second chip substrate 210 may be adjacent to the second semiconductor substrate 215, and the second surface 210b of the second chip substrate 210 may be adjacent to the second semiconductor element layer 220.

The second semiconductor chip 200 includes a plurality of second through vias 225. The second through vias 225 may be formed in the second chip substrate 210. The second through vias 225 may penetrate the second semiconductor substrate 215.

The second through vias 225 include second grounding through vias 226 and second signal/power through vias 227. The second grounding through vias 226 are connected to, for example, the ground region. The second signal/power through vias 227 may supply power or operation signals, etc. to the semiconductor element layers included in the stacked chip structure 40.

Second connection terminals 230 may be formed on the second surface 210b of the second chip substrate 210. The second connection terminals 230 may be disposed between the second semiconductor chip 200 and the first semiconductor chip 100. Although the first connection terminals 230 are shown in FIG. 1 to have a ball shape, the present disclosure is not limited thereto. It is to be understood that the second connection terminals 230 may be of a solder hump type, each of which consists of a pillar and a solder ball coupled with the pillar.

The third semiconductor chip 300 may be disposed on top of the second semiconductor chip 200. The second semiconductor chip 200 may be disposed between the third semiconductor chip 300 and the first semiconductor chip 100. The third semiconductor chip 300 may be disposed on the first surface 210a of the second chip substrate 210. The third semiconductor chip 300 may include a third chip substrate 310 and a plurality of third through vias 325.

The third chip substrate 310 may include a first surface 310a and a second surface 310b opposite to the first surface 310a. The third chip substrate 310 may include a third semiconductor substrate 315 and a third semiconductor element layer 320. The first surface 310a of the third chip substrate 310 may be adjacent to the third semiconductor substrate 315. The second surface 310b of the third chip substrate 310 may be adjacent to the third semiconductor element layer 320.

The third semiconductor chip 300 includes a plurality of third through vias 325. The third through vias 325 may be formed in the third chip substrate 310. The third through vias 325 may penetrate the third semiconductor substrate 315.

The third through vias 325 include third grounding through vias 326 and third signal/power through vias 327. The third grounding through vias 326 are connected to, for example, the ground region. The third signal/power through vias 327 may supply power or operation signals, etc. to the semiconductor element layers included in the stacked chip structure 40.

Third connection terminals 330 may be formed on the second surface 310b of the third chip substrate 310. The third connection terminals 330 may be disposed between the third semiconductor chip 300 and the second semiconductor chip 200. Although the first connection terminals 330 shown in FIG. 1 have a ball shape, the present disclosure is not limited thereto. It is to be understood that the third connection terminals 330 may be of a solder bump type, each of which consists of a pillar and a solder ball coupled with the pillar.

The fourth semiconductor chip 400 may be disposed on top of the third semiconductor chip 300. The third semiconductor chip 300 may be disposed between the fourth semiconductor chip 400 and the second semiconductor chip 200. The fourth semiconductor chip 400 may be disposed on the first surface 310a of the third chip substrate 310. The fourth semiconductor chip 400 may include a fourth chip substrate 410 and a plurality of fourth through vias 425.

The fourth chip substrate 410 may include a first surface 410a and a second surface 410b opposed to the first surface 410a. The fourth chip substrate 410 may include a fourth semiconductor substrate 415 and a fourth semiconductor element layer 420. The fourth surface 410a of the fourth chip substrate 410 may be adjacent to the fourth semiconductor substrate 415, and the second surface 410b of the fourth chip substrate 410 may be adjacent to the fourth semiconductor element layer 420. The first surface 410a of the fourth chip substrate 410 may be the top surface of the stacked chip structure 40 and may be directly below the shielding layer 70.

The fourth semiconductor chip 400 includes a plurality of fourth through vias 425. The fourth through vias 425 may be formed in the fourth chip substrate 410. The fourth through vias 425 may penetrate the fourth semiconductor substrate 415.

The fourth through vias 425 include fourth grounding through vias. It is to be noted that the fourth through vias 425 need not include fourth signal/power through vias. The fourth through vias 425 are connected to, for example, the ground region.

For example, the number of the third through vias 325 may be equal to the number of the first through vias 125 and the number of the second through vias 225.

In the semiconductor package, according to exemplary embodiments of the present disclosure, the number of fourth through vias 425 may be different from the number of first through vias 125, the number of second through vias 225, and the number of third vias 325. Because the fourth through vias 425 include no fourth signal/power through via, the number of the fourth through vias 425 may be smaller than each of the number of the first through vias 125, the number of the second through vias 225, and the number of the third through vias 325.

Fourth connection terminals 430 may be formed on the second surface 410b of the fourth chip substrate 410. The fourth connection terminals 430 may be disposed between the fourth semiconductor chip 400 and the third semiconductor chip 300. Although the first connection terminals 430 are shown in FIG. 1 to have a ball shape, the present disclosure is not limited thereto. It is to be understood that the fourth connection terminals 430 may be of a solder bump type, each of which consists of a pillar and a solder ball coupled with the pillar.

According to exemplary embodiments of the present disclosure, the first semiconductor chip 100 and the second semiconductor chip 200 may be directly bonded to each other without the second connection terminals 230. The second semiconductor chip 200 and the third semiconductor chip 300 may be directly bonded to each other without the third connection terminals 330. The third semiconductor chip 300 and the fourth semiconductor chip 400 may be directly bonded to each other without the third connection terminals 330.

In FIG. 1, the number of each of the first to third through vias 125, 225 and 325 is six, and the number of the fourth through vias 425 is two. It is, however, to be understood that the present disclosure is not limited thereto and any number of through vias may be present for any chip. In addition, in FIG. 1, the number of the first to third signal/power through vias 127, 227 and 327 is four, and the number of the first to fourth grounding through vias 126, 226, 326 and 426 is two. It is, however, to be understood that the present disclosure is not limited thereto and any number of signal/power through vias and grounding through vias may be present for any chip. In addition, in FIG. 1, the first signal/power through vias 127 are disposed between the first grounding through vias 126, the second signal/power through vias 227 are disposed between the second grounding through vias 226, and the third signal/power through vias 327 are disposed between the third grounding through vias 326. It is, however, to be understood that the present disclosure is not limited thereto and the through vias may be alternatively arranged.

The filth semiconductor chip 500 may be mounted on the first surface 50a of the mounting substrate 50. The fifth semiconductor chip 500 may be electrically connected to the mounting substrate 50.

The fifth semiconductor chip 500 may be disposed such that it is spaced apart front the stacked chip structure 40. The fifth semiconductor chip 500 may be spaced apart from the stacked chip structure 40 in the horizontal direction (x-direction).

The fifth semiconductor chip 500 may be a logic semiconductor chip. The fifth semiconductor chip 500 may be a microprocessor and may be a central processing unit (CPU), a controller, or an application specific integrated circuit (ASIC), for example. According to exemplary embodiments of the present disclosure, the fifth semiconductor chip 500 may be an AP (Application Processor) used in a mobile phone or a smartphone.

The fifth semiconductor chip 500 may include a fifth chip substrate 510. The fifth chip substrate 510 may include a first surface 510a and a second surface 510b opposite to the first surface 510. The fifth chip substrate 510 may include a fifth semiconductor substrate 515 and a fifth semiconductor element layer 520. The first surface 510a of the fifth chip substrate 510 may be adjacent to the fifth semiconductor substrate 515, and the second surface 510b of the fifth chip substrate 510 may be adjacent to the fifth semiconductor element layer 520. The first surface 510a of the fifth chip substrate 510 may be the upper surface of the fifth semiconductor chip 500.

Fifth connection terminals 530 may be formed on the second surface 510b of the fifth chip substrate 510. The fifth connection terminals 530 may be disposed between the fifth semiconductor chip 500 and the mounting substrate 50. Although the first connection terminals 530 shown in FIG. 1 have a ball shape, the present disclosure is not limited thereto. It is to be understood that the fifth connection terminals 530 may be of a solder bump type, each of which consists of a pillar and a solder ball coupled with the pillar.

A first inter-chip molding material 140 may be disposed between the mounting substrate 50 and the first semiconductor chip 100. The first inter-chip molding material 140 may be disposed between the first surface 50a of the mounting substrate and the second surface 110b of the first chip substrate 110. The first inter-chip molding material 140 may cover the first connection terminals 130.

The second inter-chip molding material 240 may be disposed between the first semiconductor chip 100 and the second semiconductor chip 200. The second inter-chip molding material 240 may cover the second connection bumps 230.

The third inter-chip molding material 340 may be disposed between the second semiconductor chip 200 and the third semiconductor chip 300. The third inter-chip molding material 340 may cover the third connection bumps 330.

The fourth inter-chip molding material 440 may be disposed between the third semiconductor chip 300 and the fourth semiconductor chip 400. The fourth inter-chip molding material 440 may cover the fourth connection bumps 430.

A fifth inter-chip molding material 540 may be disposed between the mounting substrate 50 and the fifth semiconductor chip 500. The fifth inter-chip molding material 540 may be disposed between the first surface 50a of the mounting substrate and the second surface 510b of the fifth chip substrate 510. The fifth inter-chip molding material 540 may cover the fifth connection terminals 530.

Each of the first to fifth inter-chip molding materials 140, 240, 340, 440 and 540 may, for example, include an insulating material.

Although the first inter-chip molding material 140 is not illustrated as being in contact with the fifth inter-chip molding material 540 in FIG. 1, the present disclosure is not limited thereto, and the first inter-chip molding material 140 may well be in contact with the fifth inter-chip molding material 540. For example, they may be a continuous inter-chip molding material.

The package molding material 60 may be disposed on the mounting substrate 50. For example, the package molding material 60 may be disposed on the first surface 50a of the mounting substrate 50.

The package molding material 60 may cover the sidewalls of the stacked chip structure 40 and the sidewalls of the fifth semiconductor chip 500. The package molding material 60 may cover the sidewalls of each of the first to fourth semiconductor chips 100, 200, 300, and 400. The package molding material 60 may include an insulating material.

In the semiconductor package, according to exemplary embodiments of the present disclosure, the top surface of the stacked chip structure 40 might not be covered by the package molding material 60. For example, the first surface 410a of the fourth chip substrate and the first surface 510a of the fifth chip substrate 510 may be exposed by the package molding material 60. The package molding material 60 might not cover the top surface of the stacked chip structure 40 and the upper surface of the fifth semiconductor chip 500.

The shielding layer 70 may be disposed on the package molding material 60, the stacked chip structure 40, and the fifth semiconductor chip 500. The shielding layer 70 may be extended along the sidewalls and the upper surfaces of the package molding material 60. The shielding layer 70 may be extended along the top surface of the stacked chip structure 40 and the upper surface of the fifth semiconductor chip 500. The shielding layer 70 may be extended along the sidewalk of the mounting substrate 50.

The shielding layer 70 may come in contact with the top surface of the stacked chip structure 40. The shielding layer 70 may be connected to the fourth through vias 425. The shielding layer 70 may be connected to the fourth grounding through vias.

The shielding layer 70 may be in contact with the fifth semiconductor chip 500. For example, the shielding layer 70 may be in contact with the upper surface of the fifth semiconductor chip 500 exposed by the package molding material 60.

The shielding layer 70 may include a metallic material. For example, the shielding layer 70 may include silver (Ag), aluminum (Al), copper (Cu), platinum (Pt), zinc (Zn), nickel (Ni), iron (Fe), and/or an alloy of one or more of these metals.

The shielding layer 70 is in contact with the ground region, so that the semiconductor package can shield the semiconductor chips 100, 200, 300, 400, and 500 from electromagnetic waves that might exist outside of the semiconductor package and thereby prevent electromagnetic interference. By doing so, the shielding layer 70 can prevent breakage and malfunction of the semiconductor package, and provide operational reliability. In addition, the shielding layer 70 may also block electromagnetic waves that are produced by the various semiconductor chips 100, 200, 300, 400, and 500 from exiting the semiconductor package, thereby preventing malfunction of an adjacent semiconductor device or other proximate circuit elements. The shielding layer 70 may also serve as a heat dissipating member for dissipating heat generated in the stacked chip structure 40 and/or the fifth semiconductor chip 500 to the outside of the semiconductor package.

Although the shielding layer 70 is shown as a single layer in FIG. 1, the present disclosure is not limited thereto. It is to be understood that the shielding layer 70 may be implemented as a stack of conductive layers.

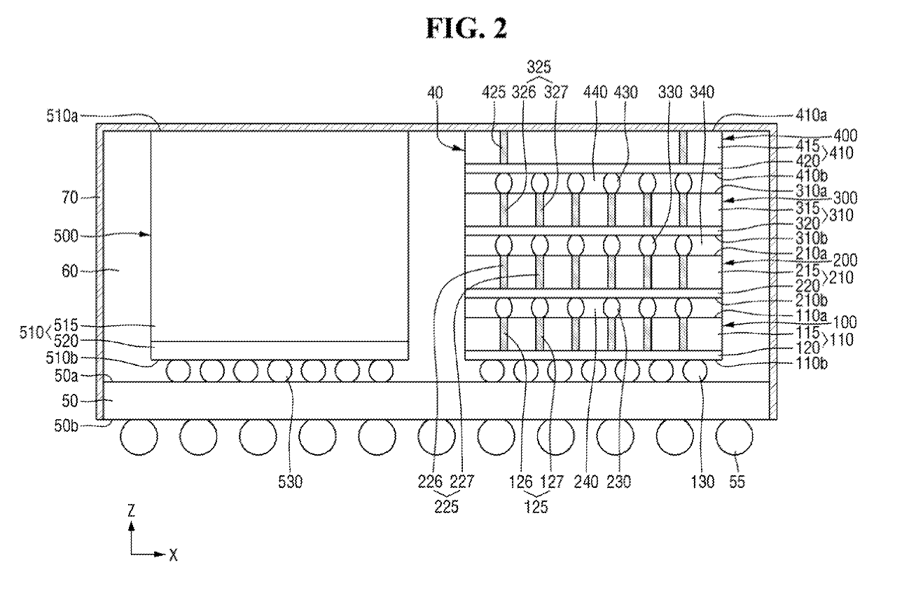

FIG. 2 is a schematic diagram illustrating a semiconductor package according to exemplary embodiments of the present disclosure. Descriptions will be focused on the differences between the semiconductor package of FIG. 2 and that of FIG. 1 for convenience of illustration. It is to be understood that the various elements shown herein may be at least similar to corresponding elements that have already been described.

Referring to FIG. 2, in a semiconductor package according to exemplary embodiments of the present disclosure, a part of the package molding material 60 may be interposed between the mounting substrate 50 and the stacked chip structure 40, and between the mounting substrate 50 and the fifth semiconductor ship 500.

The package molding material 60 may cover the first connection bumps 130 and the fifth connection bumps 530.

The package molding material 60 may work as a first inter-chip molding material 140 (see FIG. 1) between the mounting substrate 50 and the first semiconductor chip 100, and a fifth inter-chip molding material 540 (see FIG. 1) between the mounting substrate 50 and the fifth semiconductor chip 500.

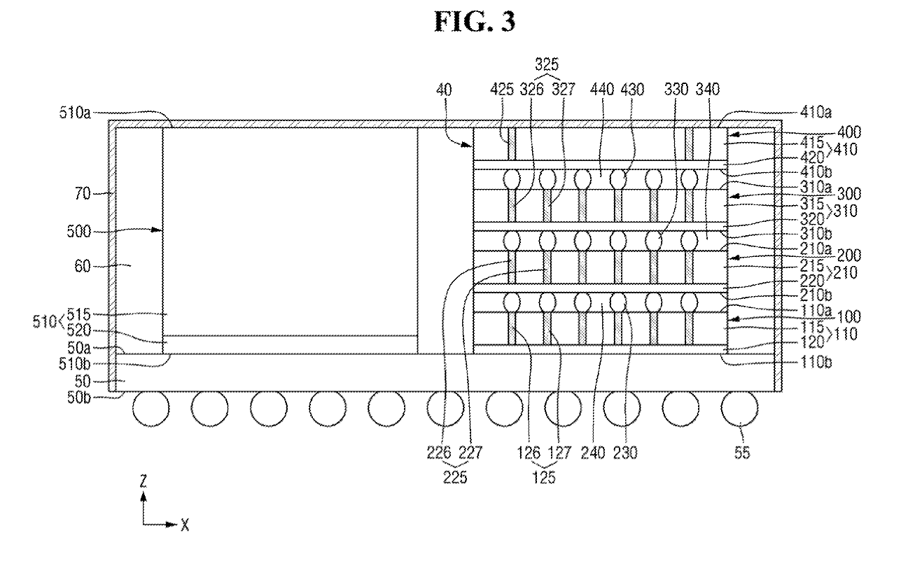

FIG. 3 is a schematic diagram illustrating a semiconductor package according to exemplary embodiments of the present disclosure. Descriptions will be focused on the differences between the semiconductor package of FIG. 3 and that of FIG. 1 for convenience of illustration. It is to be understood that the various elements shown herein may be at least similar to corresponding elements that have already been described.

Referring to FIG. 3, in a semiconductor package, according to exemplary embodiments of the present disclosure, the stacked chip structure 40 and the fifth semiconductor chip 500 may be in contact with the mounting substrate 50. The first semiconductor chip 100 may come in contact with the mounting substrate 50.

The first connection terminals 130 (see FIG. 1) might not be disposed between the first semiconductor chip 100 and the mounting substrate 50. The fifth connection terminals 530 (see FIG. 1) might not be disposed between the fifth semiconductor chip 500 and the mounting substrate 50.

After the package molding material 60 covering the stacked chip structure 40 and the fifth semiconductor chip 500 are formed, a mourning substrate 50 connected to the first semiconductor element layer 120 and the fifth semiconductor element layer 520 may be formed on the second surface 110b of the first chip substrate 110 and the second surface 510b of the fifth chip substrate 510.

The mounting substrate 50 may be, for example, a redistributed layer (RDL) substrate.

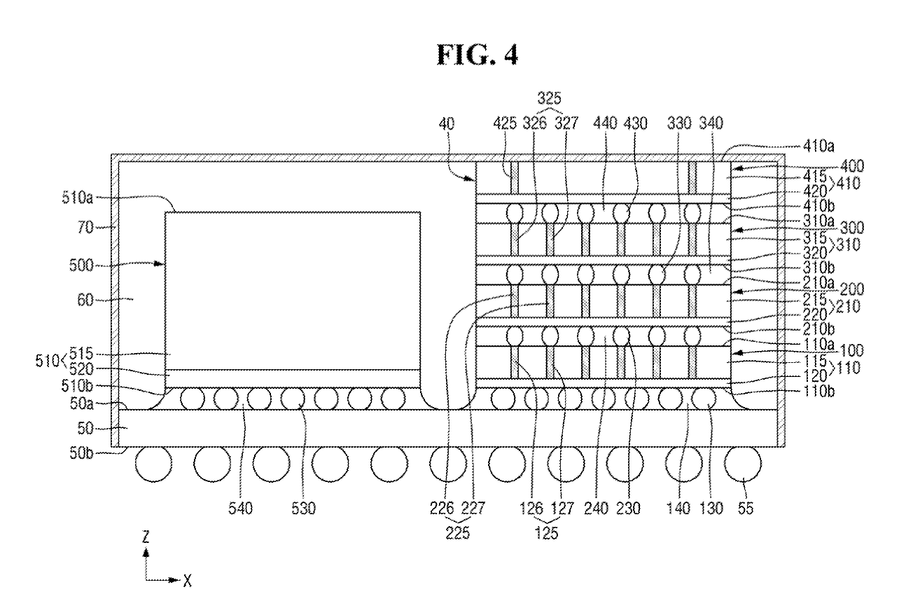

FIG. 4 is a schematic diagram illustrating a semiconductor package according to exemplary embodiments of the present disclosure. Descriptions will be focused on the differences between the semiconductor package of FIG. 4 and that of FIG. 1 for convenience of illustration. It is to be understood that the various elements shown herein may be at least similar to corresponding elements that have already been described.

Referring to FIG. 4, in a semiconductor package, according to exemplary embodiments of the present disclosure, the package molding material 60 covers the upper surface of the fifth semiconductor chip 500 as well.

A part of the package molding material 60 may be interposed between the upper surface of the fifth semiconductor chip 500 and the shielding layer 70. The semiconductor chip 500 might not be in contact with the shielding layer 70.

While the top surface of the stacked chip structure 40 may be exposed by the package molding material 60, the upper surface of the fifth semiconductor chip 500 might not be exposed by the package molding material 60.

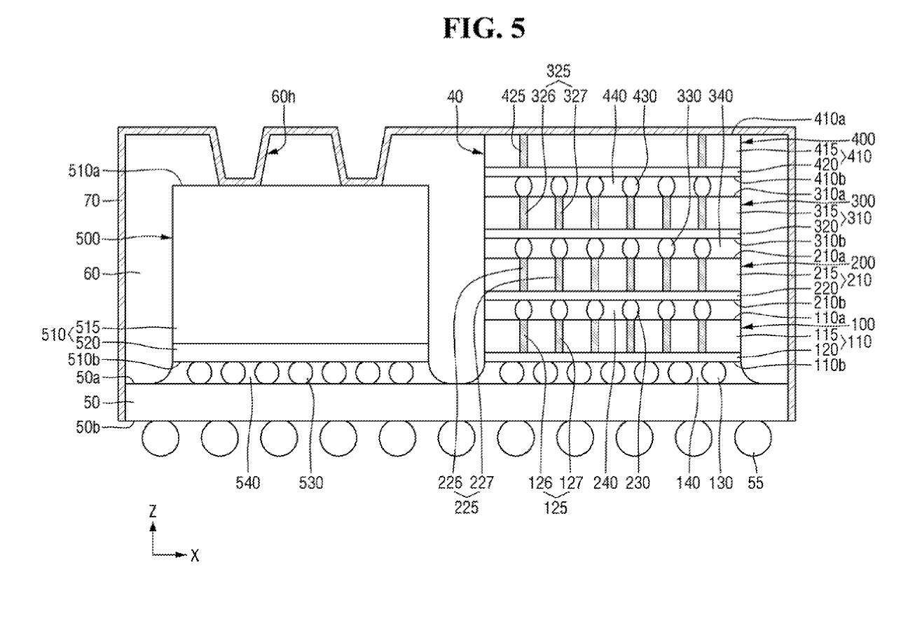

FIG. 5 is a schematic diagram illustrating a semiconductor package according to exemplary embodiments of the present disclosure. Descriptions will be focused on the differences between the semiconductor device of FIG. 5 and that of FIG. 4 for convenience of illustration. It is to be understood that the various elements shown herein may be at least similar to corresponding elements that have already been described.

Referring to FIG. 5, in the semiconductor device, according to exemplary embodiments of the present disclosure, the shielding layer 70 may be in contact with the fifth semiconductor chip 500.

The package molding material 60 may include an exposure hole 60h for exposing the fifth semiconductor chip 500. The exposure hole 60h may expose the upper surface of the fifth semiconductor chip 500.

The shielding layer 70 may be extended along the exposure hole 60h. The shielding layer 70 may come in contact with at least a part of the upper surface of the fifth semiconductor chip 500 exposed by the exposure hole 60h.

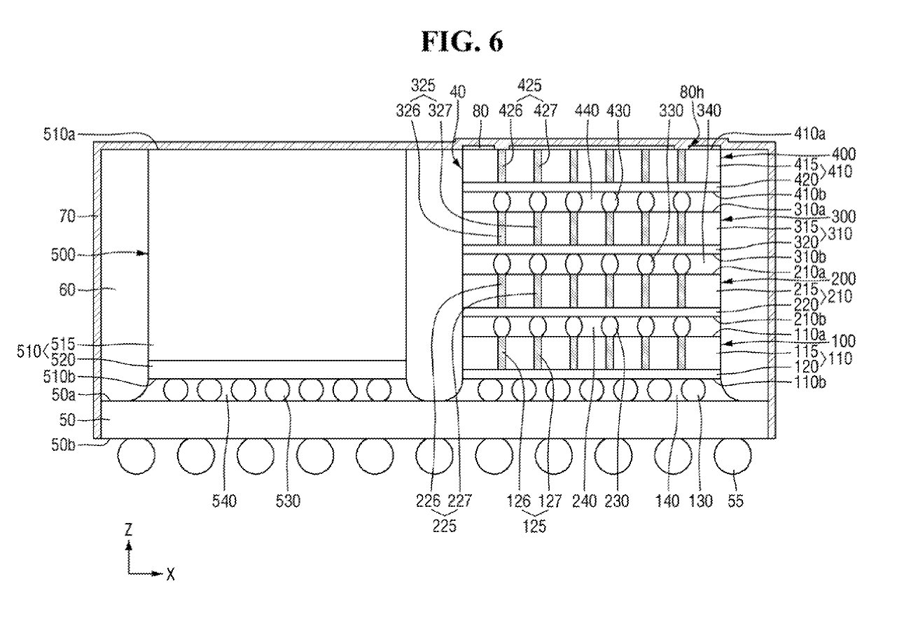

FIG. 6 is a schematic diagram illustrating a semiconductor package according to exemplary embodiments of the present disclosure. Descriptions will be focused on the differences between the semiconductor package of FIG. 6 and that of FIG. 1 for convenience of illustration. It is to be understood that the various elements shown herein may be at least similar to corresponding elements that have already been described.

Referring to FIG. 6, a semiconductor package, according to exemplary embodiments of the present disclosure, may further include an inserted insulating layer 80 extended between the shielding layer 70 and the stacked chip structure 40.

The fourth through via 425 includes fourth grounding through vias 426 and fourth signal/power through vias 427. For example, the number of the fourth through vias 425 may be equal to the number of the third through vias 325.

Some of the fourth through vias 425 are not connected to the Shielding layer 70. For example, among the fourth through vias 425, the fourth grounding through vias 426 are connected to the shielding layer 70, whereas the fourth signal/power through vias 427 are not connected to the shielding layer 70.

In a semiconductor package, according to exemplary embodiments of the present disclosure, some of the fourth through vias 425 are connected to the shielding layer 70 while the others of the fourth through vias 425 are not connected to the shielding layer 70.

The inserted insulating layer 80 includes holes 80h for exposing some of the fourth through vias 425. The shielding layer 70 may be connected to some of the fourth through vias 425 through the holes 80h.

The holes 80h of the inserted insulating layer 80 expose the fourth grounding through vias 426. The shielding layer 70 may be connected to the fourth grounding through vias 426 through the holes 80h.

The inserted insulating layer 80 covers the fourth signal/power through vias 427. The fourth signal/power through vias 427 may be exposed by the fourth chip substrate 410, like the fourth grounding through vias 426. Since the inserted insulating layer 80 covers the fourth signal/power through vias 427, the shielding layer 70 is not connected to the fourth signal/power through vias 427.

The inserted insulating layer 80 may include an inorganic material layer and/or an organic material layer.

In a semiconductor package, according to exemplary embodiments of the present disclosure, the inserted insulating layer 80 might not be extended between the upper surface of the fifth semiconductor chip 500 and the shielding layer 70.

Although the inserted insulating layer 80 is not extended along the upper surface of the package molding material 60 in FIG. 6, the present disclosure is not limited thereto and the inserted insulating layer 80 may well extend along at least part of the upper surface of the package molding material 60.

In addition, although the inserted insulating layer 80 is illustrated as being extended along the top surface of the stacked chip structure 40 except for the portion where the fourth ground through vias 426 are exposed, the present disclosure is not limited thereto. It is to be understood that the inserted insulating layer 80 may cover the portions where the fourth signal/power through vials 427 are exposed. The inserted insulating layer 80 need only insulate the shielding layer 70 from the fourth signal/power through vias 427.

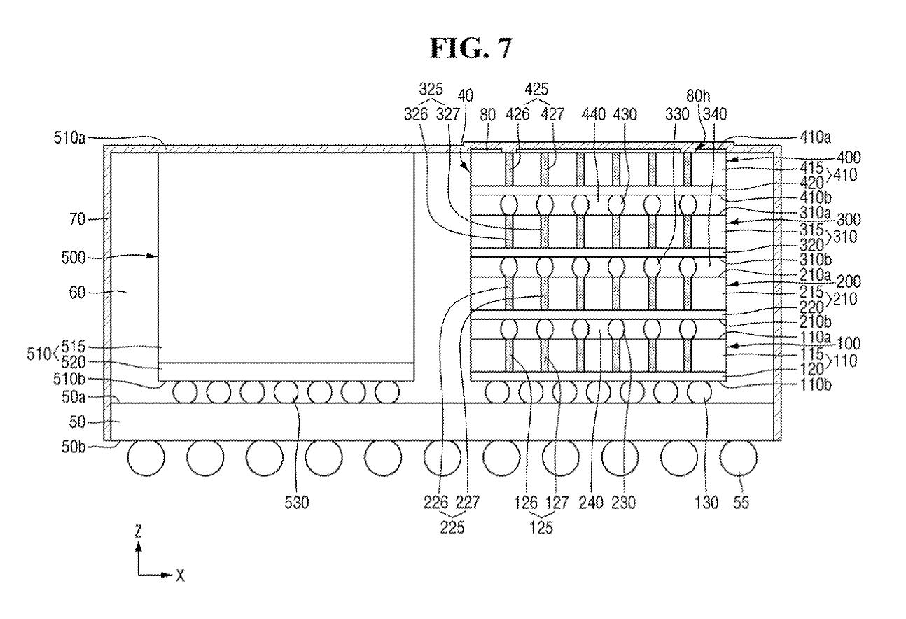

FIG. 7 is a schematic diagram illustrating a semiconductor package according to exemplary embodiments of the present disclosure. Descriptions will be focused on the differences between the semiconductor package of FIG. 7 and that of FIG. 6 for convenience of illustration. It is to be understood that the various elements shown herein may be at least similar to corresponding elements that have already been described.

Referring to FIG. 7, in a semiconductor package, according to exemplary embodiments of the present disclosure, a part of the package molding material 60 may be interposed between the mounting substrate 50 and the stacked chip structure 40, and between the mounting substrate 50 and the fifth semiconductor ship 500.

The package molding material 60 may cover the first connection bumps 130 and the fifth connection bumps 530.

The package molding material 60 may work as a first inter-chip molding material 140 (see FIG. 6) between the mounting substrate 50 and the first semiconductor chip 100, and a fifth inter-chip molding material 540 (see FIG. 6) between the mounting substrate 50 and the fifth semiconductor chip 500.

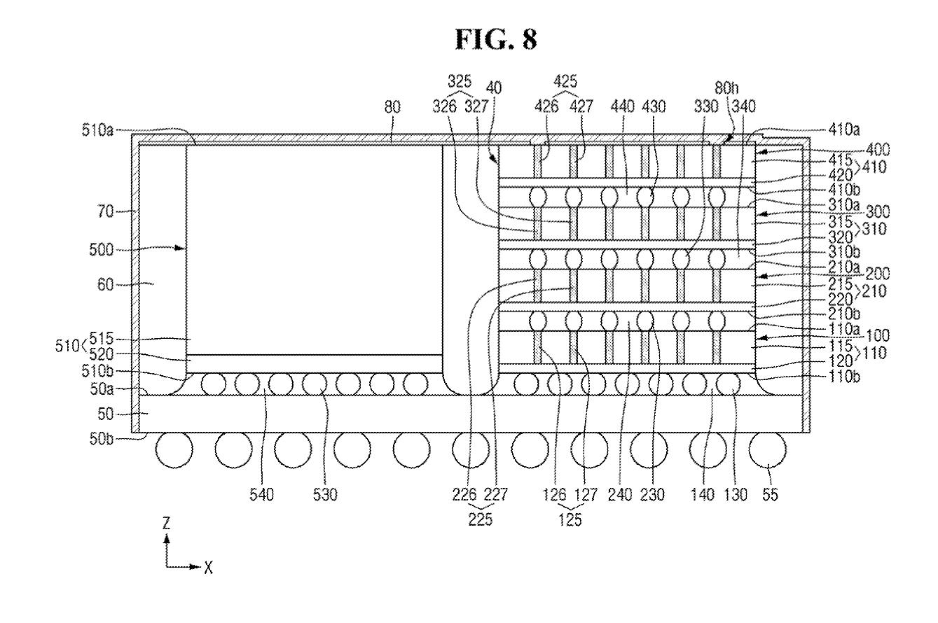

FIG. 8 is a schematic diagram illustrating a semiconductor package according to exemplary embodiments of the present disclosure. Descriptions will be focused on the differences between the semiconductor package of FIG. 8 and that of FIG. 6 for convenience of illustration. It is to be understood that the various elements shown herein may be at least similar to corresponding elements that have already been described.

Referring to FIG. 8, in a semiconductor package, according to exemplary embodiments of the present disclosure, the inserted insulating layer 80 may be disposed between the shielding layer 70 and the fifth semiconductor chip 500. The inserted insulating layer 80 may be extended between the shielding layer 70 and the fifth semiconductor chip 500.

The inserted insulating layer 80 may be extended along the upper surface of the fifth semiconductor chip 500, the top surface of the stacked chip structure 40, and the upper surface of the package molding material 60. Unlike the arrangement shown in the drawings, the inserted insulating layer 80 may expose a part of the fifth semiconductor chip 500.

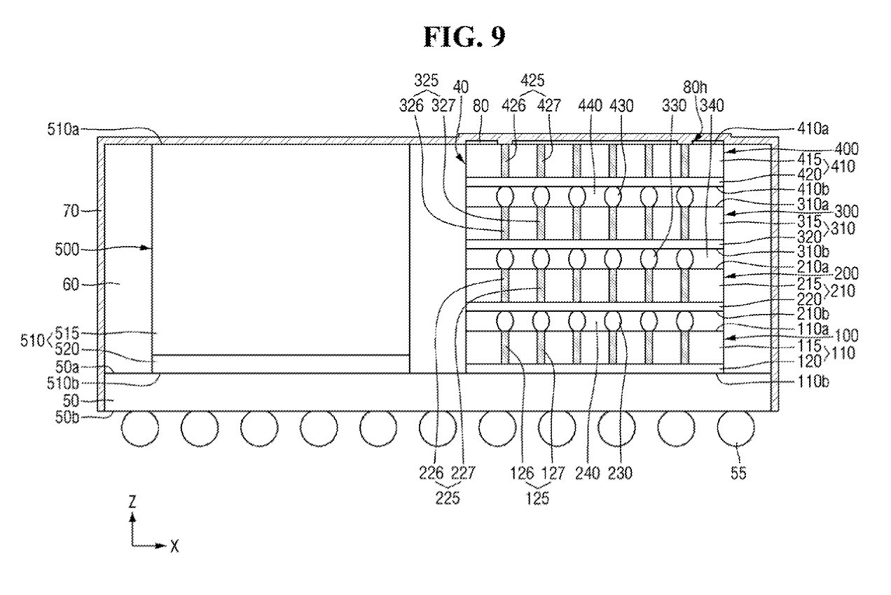

FIG. 9 is a schematic diagram for illustrating a semiconductor package according to exemplary embodiments of the present disclosure. Descriptions will be focused on the differences between the semiconductor package of FIG. 9 and that of FIG. 6 for convenience of illustration. It is to be understood that the various elements shown herein may be at least similar to corresponding elements that have already been described.

Referring to FIG. 9, in a semiconductor package, according to exemplary embodiments of the present disclosure, the stacked chip structure 40 and the fifth semiconductor chip 500 may be in contact with the mounting substrate 50. The first semiconductor chip 100 may come in contact with the mounting substrate 50.

The first connection terminals 130 (see FIG. 1) might not be disposed between the first semiconductor chip 100 and the mounting substrate 50. The fifth connection terminals 530 (see FIG. 1) might not be disposed between the fifth semiconductor chip 500 and the mounting substrate 50.

The mounting substrate 50 may be, for example, a redistributed layer (RDL) substrate.

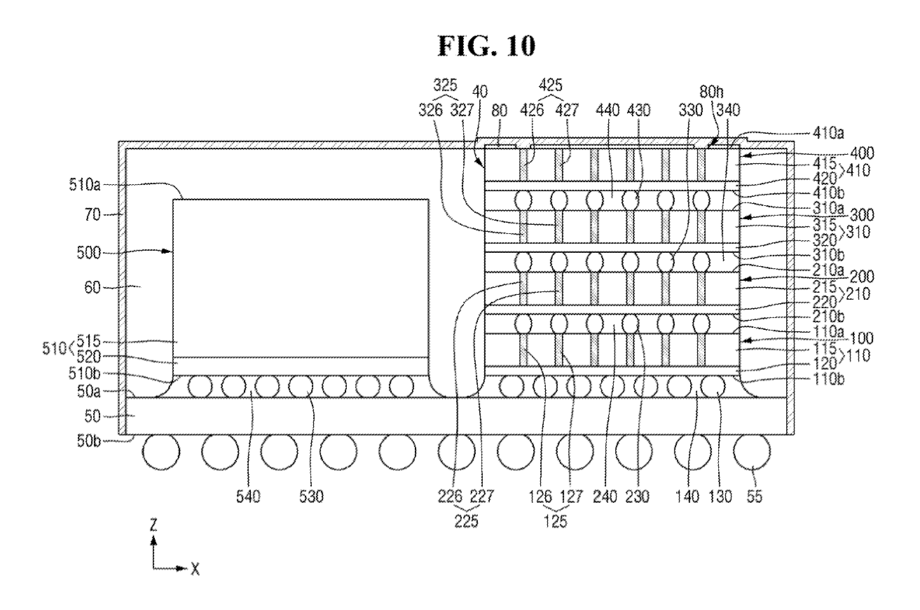

FIG. 10 is a schematic diagram for illustrating a semiconductor package according to exemplary embodiments of the present disclosure. Descriptions will be focused on the differences between the semiconductor package of FIG. 10 and that of FIG. 6 for convenience of illustration. It is to be understood that the various elements shown herein may be at least similar to corresponding elements that have already been described.

Referring to FIG. 10, in a semiconductor package according to exemplary embodiments of the present disclosure, the package molding material 60 may be disposed between the upper surface of the fifth semiconductor chip 500 and the shielding layer 70.

The package molding material 60 covers the upper surface of the fifth semiconductor chip 500. The semiconductor chip 500 might be not in contact with the shielding layer 70.

While the top surface of the stacked chip structure 40 may be exposed from the package molding material 60, the upper surface of the fifth semiconductor chip 500 might not be exposed from the package molding material 60.

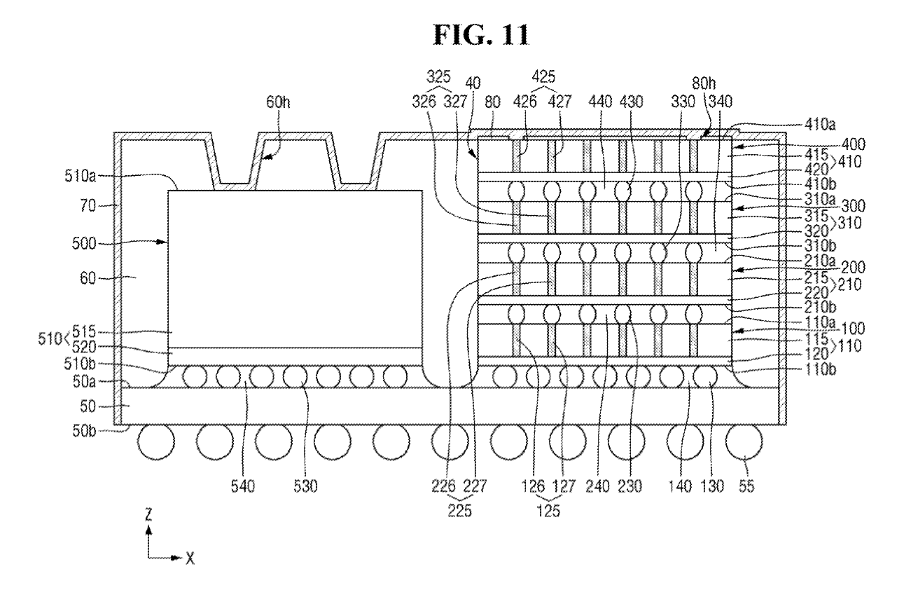

FIG. 11 is a schematic diagram for illustrating a semiconductor package according to exemplary embodiments of the present disclosure. Descriptions will be focused on the differences between the semiconductor package of FIG. 11 and that of FIG. 10 for convenience of illustration. It is to be understood that the various elements shown herein may be at least similar to corresponding elements that have already been described.

Referring to FIG. 11, in the semiconductor device according to exemplary embodiments of the present disclosure, the shielding layer 70 may be in contact with the fifth semiconductor chip 500.

The package molding material 60 may include an exposure hole 60h for exposing the fifth semiconductor chip 500. The exposure hole 60h may expose the upper surface of the fifth semiconductor chip 500.

The shielding layer 70 may be extended along the exposure hole 60h. The shielding layer 70 may come in contact with at least a part of the upper surface of the fifth semiconductor chip 500 exposed by the exposure hole 60h.

Exemplary embodiments described herein are illustrative, and many variations can be introduced without departing from the spirit of the disclosure or from the scope of the appended claims. For example, elements and/or features of different exemplary embodiments may be combined with each other and/or substituted for each other within the scope of this disclosure and appended claims.

What is claimed is:

1. A semiconductor package, comprising:
a substrate comprising a first surface and a second surface opposite to the first surface;
a vertically stacked chip structure mounted on the first surface of the substrate, the vertically stacked chip structure comprising a first semiconductor chip and a second semiconductor chip disposed on the first semiconductor chip;
a third semiconductor chip mounted on the first surface of the substrate and spaced apart horizontally from the vertically stacked chip structure;
a package molding material disposed on the first surface of the substrate and covering sidewalls of the vertically stacked chip structure and covering sidewalls of the third semiconductor chip; and
an electromagnetic shielding layer extended along sidewalls of the package molding material and along an upper surface of the package molding material,
wherein the first semiconductor chip is disposed between the second semiconductor chip and the substrate,
wherein the first semiconductor chip is connected to a first grounding through via and a first signal/power through via,
wherein the second semiconductor chip is connected to a second grounding through via, and
wherein the electromagnetic shielding layer is connected to the second grounding through via.

2. The semiconductor package of claim 1, wherein the second semiconductor chip is connected to a second signal/power through via, and
wherein the second signal/power through via is not connected to the electromagnetic shielding layer.

3. The semiconductor package of claim 2, further comprising:
an inserted insulating layer disposed between the second semiconductor chip and the electromagnetic shielding layer and covering the second signal/power through via,
wherein the inserted insulating layer is not present between the electromagnetic shielding layer and the third semiconductor chip.

4. The semiconductor package of claim 2, further comprising:
an inserted insulating layer disposed between the second semiconductor chip and the electromagnetic shielding layer and disposed between the third semiconductor chip and the electromagnetic shielding layer and covering the second signal/power through via.

5. The semiconductor package of claim 1, wherein the second semiconductor chip is not connected to a signal/power through via.

6. The semiconductor package of claim 1, wherein the third semiconductor chip is in contact with the electromagnetic shielding layer.

7. The semiconductor package of claim 1, wherein an upper surface of the second semiconductor chip is exposed by the package molding material, and wherein the package molding material covers an upper surface of the third semiconductor chip.

8. The semiconductor package of claim 1, wherein a part of the package molding material is interposed between the vertically stacked chip structure and the substrate and between the third semiconductor chip and the substrate.

9. The semiconductor package of claim 1, further comprising:
a first inter-chip molding material disposed between the vertically stacked chip structure and the substrate; and
a second inter-chip molding material disposed between the third semiconductor chip and the substrate.

10. The semiconductor package of claim 1, wherein the substrate is a redistributed layer (RDL) substrate or a printed circuit board (PCB) substrate.

11. A semiconductor package, comprising:
a substrate comprising a first surface and a second surface opposite to the first surface;
a first semiconductor chip mounted on the first surface of the substrate and connected to a plurality of first through vias;
a second semiconductor chip mounted on the second surface of the substrate and spaced apart horizontally from the first semiconductor chip;
a package molding material disposed on the first surface of the substrate and covering sidewalls of the first semiconductor chip and covering sidewalls of the second semiconductor chip; and
an electromagnetic shielding layer extended along sidewalls of the package molding material and an upper surface of the package molding material and connected to some of the plurality of first through vias.

12. The semiconductor package of claim 11, wherein the plurality of first through vias comprises first grounding through vias and first signal/power through vias, and
wherein the electromagnetic shielding layer is connected to the first grounding through vias and is not connected to the first signal/power through vias.

13. The semiconductor package of claim 11, further comprising:
an inserted insulating layer disposed between the first semiconductor chip and the electromagnetic shielding layer, the inserted insulating layer comprising a plurality of holes exposing some of the plurality of first through vias,
wherein the some of the plurality of first through vias are connected to the electromagnetic shielding layer through the respective holes.

14. The semiconductor package of claim 13, wherein the inserted insulating layer is extended between the second semiconductor chip and the electromagnetic shielding layer.

15. The semiconductor package of claim 11, further comprising:
a third semiconductor chip disposed between the first semiconductor chip and the substrate.
wherein the third semiconductor chip is connected to a plurality of second through vias, and
wherein a number of first through vias in the plurality of first through vias is equal to a number of second through vias in the plurality of second through vias.

16. The semiconductor package of claim 11, wherein the second semiconductor chip is in contact with the electromagnetic shielding layer.

17. A semiconductor package, comprising:
a substrate comprising a first surface and a second surface opposite to the first surface;
a vertically stacked chip structure mounted on the first surface of the substrate, the vertically stacked chip structure comprising a first semiconductor chip and a second semiconductor chip disposed on the first semiconductor chip;
a third semiconductor chip mounted on the first surface of the substrate and spaced apart horizontally from the vertically stacked chip structure;
a package molding material disposed on the first surface of the substrate and covering sidewalls of the vertically stacked chip structure and covering sidewalls of the third semiconductor chip; and
an electromagnetic shielding layer extended along sidewalls and an upper surface of the package molding material,
wherein the second semiconductor chip is disposed at a top of the vertically stacked chip structure,
wherein the first semiconductor chip is disposed between the second semiconductor chip and the substrate,
wherein the first semiconductor chip is connected to a plurality of first through vias,
wherein the second semiconductor chip is connected to a plurality of second through vias,
wherein a number of second through vias of the plurality of second through vias is different from a number of first through vias of the plurality of first though vias, and
wherein the electromagnetic shielding layer is connected to the second through vias.

18. The semiconductor package of claim 17, wherein the number of first through vias of the plurality of first though vias is greater than the number of second through vias of the plurality of second through vias.

19. The semiconductor package of claim 18, wherein the plurality of first through vias comprises a first grounding through via and a first signal/power through via, and
wherein the plurality of second through vias comprises a second grounding through via and does not comprise a signal/power through via.

20. The semiconductor package of claim 17, wherein an upper surface of the vertically stacked chip structure and an upper surface of the third semiconductor chip are exposed by the package molding material.
